(19) United States
(12) Patent Application Publication
(10) Pub. No.: US 2019/0195236 A1
(43) Pub. Date: Jun. 27, 2019

(54) AIR BLOWER

(71) Applicant: Nidec Corporation, Kyoto (JP)

(72) Inventors: Tomoyuki TSUKAMOTO, Kyoto (JP); Takehito TAMAOKA, Kyoto (JP); Kazuhiko FUKUSHIMA, Kyoto (JP); Koji HATANAKA, Kyoto (JP)

(21) Appl. No.: 16/224,941

(22) Filed: Dec. 19, 2018

(30) Foreign Application Priority Data
Dec. 25, 2017 (JP) 2017-248020

(51) Int. Cl. F04D 29/28; H01L 23/467; H01L 23/427

(52) U.S. Cl. CPC F04D 29/282; H01L 23/427; H01L 23/467

(57) ABSTRACT

In an air blower, an exhaust extends in a first direction that is a radial component of an impeller, and includes fins. Assuming that a distance from a line segment extending from a central axis in the first direction to an array of the fins upstream of an airflow caused by rotation of the impeller is a first predetermined distance, at least a portion of the fins are disposed in a first region upstream from the first predetermined distance and in a second region downstream from the first predetermined distance. The distance between the fins in the first region is shorter than the distance between the fins in the second region.

### CROSS REFERENCE TO RELATED APPLICATIONS

This application claims the benefit of priority to Japanese Patent Application No. 2017-248020 filed on Dec. 25, 2017. The entire contents of this application are hereby incorporated herein by reference.

### BACKGROUND OF THE INVENTION

### 1. Field of the Invention

The present disclosure relates to air blowers.

### 2. Description of the Related Art

Various air blowers are known in the related art. For example, a heat sink for a semiconductor device is disclosed.

The known heat sink for a semiconductor device includes a group of fins and a blower fan. The fin group has a shape in which a large number of plates or pins are vertically arrayed on a base. The blower fan includes a fan rotating mechanism and a centrifugal fan. The fin group and the centrifugal fan each include a cover. An air intake port is disposed in the cover of the centrifugal fan in the rotational direction.

However, in the known heat sink for a semiconductor device, the direction of air flow due to the rotation of the centrifugal fan with respect to the fin extending direction is not uniform, for example, parallel to or inclined with respect to the fin extending direction. The known heat sink for a semiconductor device is configured such that the fins are disposed at regular intervals, so that air flow in the gap between the fins is interrupted in a region in which the direction of air flow is inclined or perpendicular to the fin extending direction, resulting in insufficient air volume of the air blower. Furthermore, the volume of air exhausted from the exhaust port of the fin group is non-uniform in the fin array direction.

### SUMMARY OF THE INVENTION

An air blower according to an example embodiment of the present disclosure includes an impeller centered on a central axis extending in a vertical direction, a motor to rotate the impeller about the central axis; and a housing structured to house the impeller. The housing includes a lower plate covering a lower side of the impeller, wherein the motor is fixed to the lower plate, a side wall covering a side of the impeller, and an upper plate covering an upper side of the impeller. At least one of the upper plate and the lower plate includes an air intake portion. An exhaust is disposed in a first direction that is a radial component of the impeller. The exhaust includes a plurality of fins. Assuming that a distance from a line segment extending from the central axis in the first direction to an array of the fins upstream of an airflow caused by rotation of the impeller is a first predetermined distance, at least a portion of the plurality of fins are disposed in a first region located upstream from the first predetermined distance and in a second region located downstream from the first predetermined distance. A distance between the plurality of fins disposed in the first region is shorter than a distance between the plurality of fins disposed in the second region.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a cross-sectional view of an air blower according to an example embodiment of the present disclosure.

FIG. 2A is a plan view of the air blower according to an example embodiment of the present disclosure viewed from above.

FIG. 2B is an enlarged plan view of an exhaust according to an example embodiment of the present disclosure illustrating the configuration thereof.

FIG. 3 is a plan view of an air blower with the same configuration as the configuration in FIG. 2A.

FIG. 4 is a plan view of an air blower with a heat pipe viewed from above illustrating a configuration example thereof.

FIG. 5 is a plan view of an air blower with a modification configuration concerning the distance between the fins.

FIG. 6 is a plan view of an air blower viewed from above illustrating an example embodiment in which the present disclosure is applied to a scroll air blower.

### DETAILED DESCRIPTION OF THE PREFERRED EMBODIMENTS

An example embodiment of the present disclosure will be described hereinbelow with reference to the drawings. In this specification, a direction in which a central axis C1, to be described later, extends is referred to as “vertical direction”. However, “vertical direction” is not a vertical direction when the air blower is installed in actual equipment. A radial direction about the central axis C1 is simply referred to as “radial direction” and a circumferential direction about the central axis C1 is simply referred to as “circumferential direction”. The “vertical direction” is sometimes referred to as “axial direction”.

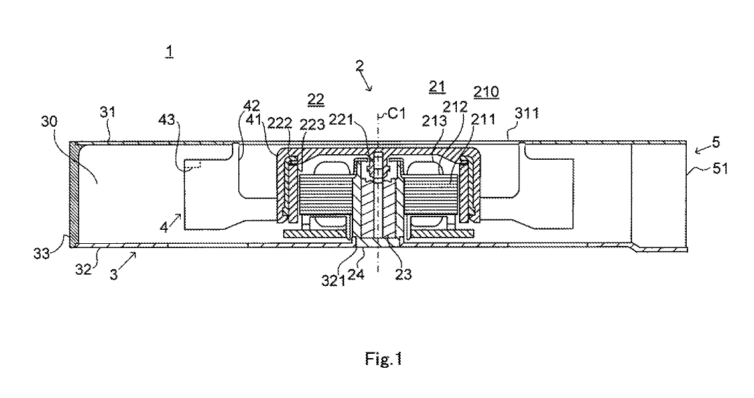

FIG. 1 is a cross-sectional view of an air blower 1 according to an example embodiment of the present disclosure. The air blower 1 is a centrifugal fan. The air blower 1 is installed in, for example, a notebook personal computer (PC), to be used in cooling components in the casing of the notebook PC.

The air blower 1 includes a motor unit 2, a housing 3, and an impeller 4. The impeller 4 is centered on a central axis C1 extending in the vertical direction. The motor unit 2 rotates the impeller 4 about the central axis C1. The housing 3 houses the motor unit 2 and the impeller 4.

The housing 3 includes an upper plate 31, a lower plate 32, and a side wall 33. The upper plate 31 covers the upper side of the impeller 4. The lower plate 32 covers the lower side of the impeller 4. The side wall 33 covers a side of the impeller 4. The motor unit 2 is fixed to the lower plate 32. The upper plate 31, the side wall 33, and the lower plate 32 constitute a wind tunnel 30 surrounding the impeller 4.

The upper plate 31 and the lower plate 32 are thin sheets made of an aluminum alloy, a stainless steel, or another metal. The side wall 33 is formed from a die-cast aluminum alloy or resin. The lower end of the side wall 33 is fixed to the periphery of the lower plate 32 by, for example, screwing. The upper plate 31 is fixed to the upper end of the side wall 33 by, for example, caulking.

The motor unit 2 is of an outer rotor type, as illustrated in FIG. 1. The motor unit 2 includes a stationary portion 21, a rotating portion 22, and a sleeve 23 serving as a bearing. The sleeve 23 has a substantially cylindrical shape centered on the central axis C1. The rotating portion 22 can be rotated about the central axis C1 with respect to the stationary portion 21 by a shaft 221, to be described later, and the sleeve 23.

The stationary portion 21 includes a stator 210 and a bearing holding portion 24. The bearing holding portion 24 houses the sleeve 23. The bearing holding portion 24 has a substantially cylindrical shape centered on the central axis C1 and is made of resin. The bearing holding portion 24 protrudes upward from the lower plate 32. The bearing holding portion 24 is fixed to a hole 321 in the lower plate 32. The lower end of the bearing holding portion 24 and the peripheral portion of the hole 321 are fastened by, for example, insert molding. The lower end of the bearing holding portion 24 and the peripheral portion of the hole 321 may not be fixed as described above but may be fixed by press-fitting or caulking.

The stator 210 has a ring shape centered on the central axis C1 and is mounted to the outer circumferential surface of the bearing holding portion 24. The stator 210 includes a stator core 211, and insulator 212, and a coil 213. The stator core 211 is a lamination of thin electromagnetic steel sheets. The inner circumferential surface of the stator core 211 is fixed to the outer circumferential surface of the bearing holding portion 24. The insulator 212 covers the surface of the stator core 211.

The rotating portion 22 includes a shaft 221, a yoke 222, and a rotor magnet 223. The shaft 221 is a rod-like member centered on the central axis C1 and extending in the vertical direction. The upper end of the shaft 221 is fixed to a cup 41 (described later) of the impeller 4. The yoke 222 has a substantially cylindrical shape centered on the central axis C1 and is fixed to the inner surface of the cup 41. The rotor magnet 223 has a substantially cylindrical shape centered on the central axis C1 and is fixed to the inner surface of the yoke 222 and faces the stator 210 in the radial direction.

The shaft 221 is inserted in the sleeve 23. The outer circumferential surface of the shaft 221 faces the inner circumferential surface of the sleeve 23 with a space therebetween. The sleeve 23 is made of an oil-retaining porous metallic material and is inserted and fixed in the bearing holding portion 24. The bearing may be a ball bearing.

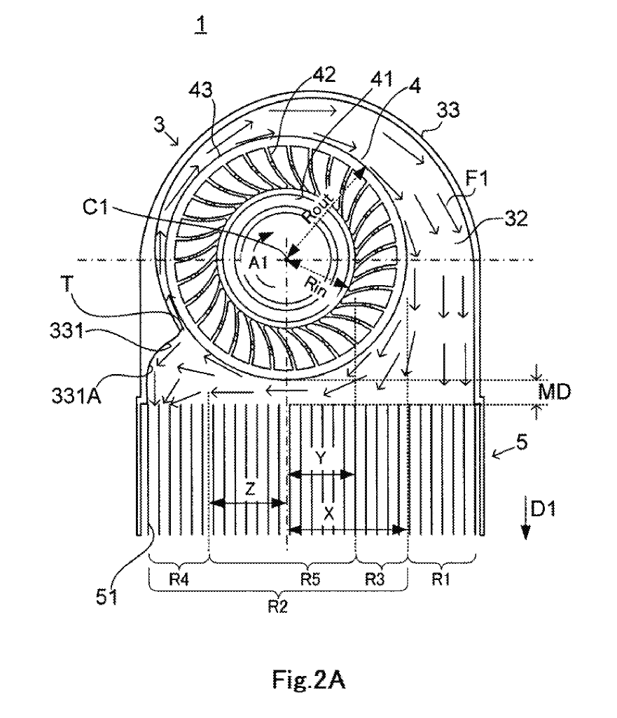

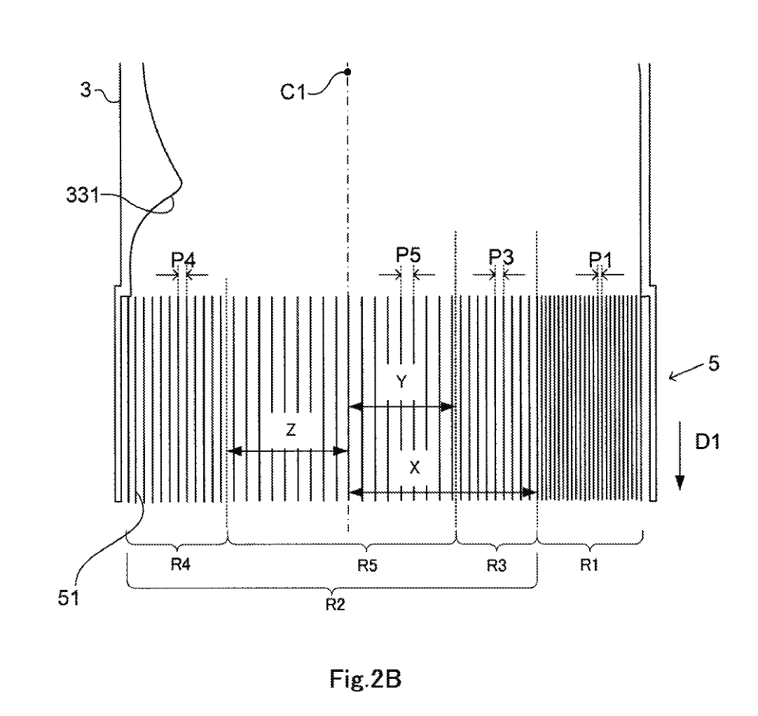

FIG. 2A is a plan view of the air blower 1 viewed from above. In FIG. 2A, the upper plate 31 is not illustrated for the sake of convenience. The impeller 4 includes the cup 41, a plurality of blades 42, and a connecting portion 43. The cup 41, the blades 42, and the connecting portion 43 are made of resin into a single unit. As illustrated in FIG. 2A, the rotational direction A1 of the impeller 4 is clockwise as viewed from above.

The cup 41 has a covered substantially cylindrical shape centered on the central axis C1 and opens downward. The plurality of blades 42 extend radially outward from the outer circumferential surface of the cup 41. The blades 42 are disposed at equal intervals in the circumferential direction. The outer circumferential ends of the blades 42 are disposed behind the inner circumferential ends in the rotational direction. This makes the blades 12 inclined with respect to the radial direction.

The connecting portion 43 connects the upper surfaces of the outer circumferential ends of the blades 42 next to each other in the circumferential direction to form a ring shape. The upper plate 31 has an air intake hole (an air intake portion) 311 (not illustrated in FIG. 2A, illustrated in FIG. 1). The air intake hole 311 is located above the impeller 4. The inner peripheral edge of the connecting portion 43 is disposed radially outside the air intake hole 311. The impeller 4 is therefore exposed from the air blower 1 through the air intake hole 311 as viewed from above.

The air intake hole may be disposed not in the upper plate 31 but in the lower plate 32 or in both of the upper plate 31 and the lower plate 32. If the air intake hole is provided in the lower plate 32, a plurality of air intake holes are disposed around the central axis C1 in the circumferential direction. In other words, at least one of the upper plate 31 and the lower plate 32 may include the air intake portion.

As illustrated in FIG. 2A, the air blower 1 includes an exhaust unit 5 disposed in a first direction D1, which is a radial component of the impeller 4. The exhaust unit 5 is formed by, for example, part of the lower plate 32, a plurality of fins 51, and part of the upper plate 31 (not illustrated in FIG. 2A). The plurality of fins 51 are arrayed in a direction perpendicular to the first direction D1. The fins 51 are plate-like members sandwiched between the upper plate 31 and the lower plate 32 from above and below and standing in the vertical direction. The plurality of fins 51 are arrayed parallel to the first direction D1. This allows the air to be exhausted in a fixed direction from the exhaust unit 5. Part of the plurality of fins 51 may be nonparallel to the first direction D1. In some embodiments, part of the fins 51 are not sandwiched between the upper plate 31 and the lower plate 32.

In the case where a heat pipe is disposed above the fins 51 (to be described later), the upper plate 31 extends to an end of the heat pipe opposite to the first direction D1. In this case, the exhaust unit 5 is constituted by part of the lower plate 32, a plurality of fins 51, and the heat pipe. The exhaust unit 5 may be made of a material different from the material of the upper plate 31 and the lower plate 32. The heat pipe may be disposed above the fins 51, with the upper plate 31 therebetween.

When the coil 213 is supplied with an electrical current, a torque about the central axis C1 is generated between the rotor magnet 223 and the stator 210. This causes the impeller 4 to rotate about the central axis C1 in the rotational direction A1. When the impeller 4 rotates, air flows into the housing 3 through the air intake hole 311. The air that has flowed into the housing 3 flows between adjacent blades 42 and accelerates radially outward. The air that has accelerated radial outward is blown radially outward of the impeller. The air that has been blown radially outward of the impeller 4 flows in the wind tunnel 30, passes through a gap between adjacent fins 51, and is discharged outward.

A more specific configuration of the exhaust unit 5 will be described with reference to FIGS. 2A and 2B. In FIG. 2A, the distance between adjacent fins 51 is regular in the array direction of the fins 51 for the sake of convenience. However, the distance between the fins 51 differs actually. The configuration is illustrated in FIG. 2B, which is an enlarged view of the exhaust unit 5. In FIG. 2A, the flow of air caused by the rotation of the impeller 4 is expressed as an airflow F1.

As illustrated in FIGS. 2A and 2B, a first predetermined distance X is assumed to be the distance from a line segment extending from the central axis C1 in the first direction D1 to the array of the fins 51 upstream of the airflow F1. A region of the exhaust unit 5 including the plurality of fins 51 includes a first region R1 upstream of the airflow F1 from the first predetermined distance X and a second region R2 other than the first region R1. In other words, the second region R2 is a region located downstream of the airflow F1 from the first predetermined distance X.

A distance P1 between the plurality of fins 51 disposed in the first region R1 is smaller than distances P3, P4, and P5 between the plurality of fins 51 disposed in the second region R2. In the first region R1, the airflow F1 is substantially parallel to the direction in which the fins 51 extend. In the second region R2, the airflow F1 is inclined with respect to or substantially perpendicular to the direction in which the fins 51 extend. Accordingly, increasing the distance between the fins 51 in the second region R2 allows the air to easily flow in the gap between the fins 51, thereby increasing the volume of air in the second region R2. Since the distances between the fins 51 in the first region R1 and the second region R2 are adjusted according to the direction in which air flows, the amount of exhaust air can be made uniform across the first region R1 and the second region R2.

In FIG. 2A and FIG. 2B, there is no other region along the joint between the first region R1 and the second region R2.

As an alternative, another region in which the fin interval differs from the distances in the first region R1 and the second region R2 may be disposed in the joint. In other words, the other region is not the essence of the present disclosure related to the first region R1 and the second region R2. This also applies to the joint between other regions, to be described below.

In other words, the air blower 1 of the present embodiment includes the impeller 4 centered on the central axis C1 extending in the vertical direction, the motor unit 2 that rotates the impeller 4 about the central axis C1, and the housing 3 that houses the impeller 4. The housing 3 includes the lower plate 32, which covers the lower side of the impeller 4 and to which the motor unit 2 is fixed, the side wall 33 covering a side of the impeller 4, and the upper plate 31 covering the upper side of the impeller 4. At least one of the upper plate 31 and the lower plate 32 includes the air intake hole 311. The exhaust unit 5 is disposed in the first direction D1, which is a radial component of the impeller 4. The exhaust unit 5 includes the plurality of fins 51. If the distance from the line segment extending from the central axis C1 in the first direction D1 to the array of the fins 51 upstream of the airflow F1 caused by the rotation of the impeller is the first predetermined distance X, at least part of the plurality of fins 51 are disposed in the first region R1 located upstream from the first predetermined distance X and in the second region R2 located downstream from the first region R1. The distance between the plurality of fins 51 disposed in the first region R1 is shorter than the distance between the plurality of fins 51 disposed in the second region R2.

Thus, increasing the distance between the fins 51 in the second region R2 in which the airflow F1 is inclined with respect to the extending direction of the fins 51 may allow the air between the fins 51 to easily flow, thereby decreasing loss in air volume between the fins 51. This may increase the air flow rate of the air blower 1. This may also make the air volume in the exhaust unit 5 uniform in the direction in which the fins 51 are arrayed.

As illustrated in FIG. 2A, the first predetermined distance X is preferably from 0.8 (Rout) to 1.2 (Rout), where Rout is the distance from the central axis C1 to the radially outer end of the blades 42 of the impeller 4.

Thus, the small distance between the fins 51 in the first region R1 in which the flow of air is substantially parallel to the direction in which the fins 51 extend may allow the air volume to be adjusted, so that the air volume in the exhaust unit 5 may be made uniform in the direction in which the fins 51 are arrayed.

As illustrated in FIG. 2A and FIG. 2B, of the distance from the line segment extending from the central axis C1 in the first direction D1 upstream of the airflow F1, a distance shorter than the first predetermined distance X is assumed to be a second predetermined distance Y. The second region R2 includes a third region R3 next to the first region R1 upstream of the airflow F1 from the second predetermined distance Y. The distance P3 between the fins 51 disposed in the third region R3 is longer than the distance P1 between the fins 51 disposed in the first region R1.

In the remaining region of the second region R2 other than the third region R3, the distance between the fins 51 in a fifth region R5 other than a fourth region R4 (to be described later) is longer than the distance in the third region R3. In other words, in FIG. 2B, the distance P5 between the fins 51 disposed in the fifth region R5 is longer than the distance P3 between the fins 51 disposed in the third region R3. In the third region R3, the airflow F1 is inclined more with respect to the direction in which the fins 51 extend than in the first region R1, and in the fifth region R5, the airflow F1 is more inclined. Adjusting the distance between the fins 51 in the third region R3 and the fifth region R5 according to the direction of the airflow F1 may reduce loss in air volume between the fins 51, thereby increasing the air volume. For the fourth region R4, there is no limitation on the distance between the fins 51 relative to the distance between the fins 51 in the third region R3. In FIG. 2B, for example, the distance P4 between the fins 51 disposed in the fourth region R4 is the same as the distance P3 between the fins 51 disposed in the third region R3.

In other words, the second predetermined distance Y, which is the distance from the line segment extending from the central axis C1 in the first direction D1 to the array of the fins upstream of the airflow F1 caused by the rotation of the impeller 4 is shorter than the first predetermined distance X. The second region R2 includes the third region R3 at the position upstream from the second predetermined distance Y and next to the first region R1. The distance between the plurality of fins 51 disposed in the third region R3 is longer than the distance between the plurality of fins 51 disposed in the first region R1 and smaller than the distance between the plurality of fins 51 disposed in the remainder of the second region R2 other than the third region R3.

Thus, adjusting the distance between the fins 51 according to the direction of air flow may reduce loss in air volume between the fins 51, increasing the air volume of the air blower 1.

As illustrated in FIG. 2A, the second predetermined distance Y is preferably from 0.8 (Rin) to 1.2 (Rin), where Rin is the distance from the central axis C1 to the radially inner ends of the blades 42.

Thus, setting the fin distance in the third region R3 in which the direction of air flow is inclined with respect to the direction in which the fins 51 extend longer than the fin distance in the first region R1 may make air between the fins 51 easy to flow to reduce loss in air volume between the fins 51, thereby increasing the air volume of the air blower 1.

As illustrated in FIG. 2A and FIG. 2B, a third predetermined distance Z is assumed to be the distance from the line segment extending from the central axis C1 in the first direction D1 to the array of the fins 51 downstream of the airflow F1. The second region R2 includes the fourth region R4 downstream of the airflow F1 from the third predetermined distance Z. The fourth region R4 is positioned most downstream of the airflow F1 in the exhaust unit 5.

In the second region R2, a region other than the third region R3 and the fourth region R4 is the fifth region R5. Of the region of the second region R2 other than the fourth region R4, the distance between the fins 51 in the fourth region R4 is shorter than the distance between the fins 51 at least in the fifth region R5. In other words, in FIG. 2B, the distance P4 between the fins 51 disposed in the fourth region R4 is shorter than the distance P5 between the fins 51 disposed in the fifth region R5. As described above, for the fourth region R4, there is no limitation on the distance between the fins 51 relative to the distance between the fins 51 in the third region R3.

The side wall 33 includes a tongued portion 331 protruding toward the impeller 4. The tongued portion 331 faces the fourth region R4 in the first direction D1 with a gap therebetween. This allows the airflow F1 caused by the rotation of the impeller 4 to be guided to the fourth region R4 using the tongued portion 331.

The tongued portion 331 includes a curved surface 331A extending from a top T facing the impeller 4 toward the fourth region R4. The curved surface 331A allows the flow of air to be smoothly guided to the fourth region R4.

The airflow F1 due to the tongued portion 331 causes the air in the fourth region R4 to flow in the extending direction of the fins 51. Therefore, decreasing the distance between the fins 51 in the fourth region R4 allows the volume of air exhausted from the fourth region R4 to be adjusted.

In other words, assuming that the distance from the line segment extending from the central axis C1 in the first direction D1 to the array of the fins 51 downstream of the airflow F1 caused by the rotation of the impeller 4 is the third predetermined distance Z, the second region R2 includes the fourth region R4 downstream from the third predetermined distance Z. The distance between the plurality of fins 51 disposed in the fourth region R4 is shorter than the distance between the plurality of fins 51 disposed in the remainder of the second region R2 other than the fourth region R4.

This causes the air in the fourth region R4 to flow to the exhaust side. Thus, setting the fin distance in the fourth region R4 short may make the air volume uniform in the array direction of the fins 51 in the exhaust unit 5.

On the line extending from the central axis C1 to the fins 51, the distance between the outer ends of the blades 42 of the impeller 4 and the inflow ends of the fins 51 is shortest at the distance MD illustrated in FIG. 2A. The fifth region R is disposed on the line segment at the position of the distance MD. At the position of the distance MD, the direction of the airflow F1 is substantially orthogonal to the extending direction of the fins 51. Therefore, disposing the fifth region R5 at the position of the distance MD in which the distance between the fins 51 is long may allow the air to flow easily through the gap between the fins 51, increasing the air volume.

In other words, the second region R2 is disposed on the line extending from the central axis C1 toward the fins 51 at the position where the distance between the outer ends of the blades 42 of the impeller 4 and the inflow ends of the fins 51 is shortest.

At the position where the distance is shortest, the flow of air is substantially orthogonal to the direction in which the fins 51 extend. This makes it difficult to exhaust the air between the fins 51. For that reason, the second region R2 is disposed to reduce loss in air volume between the fins 51, thereby increasing the air volume of the air blower 1.

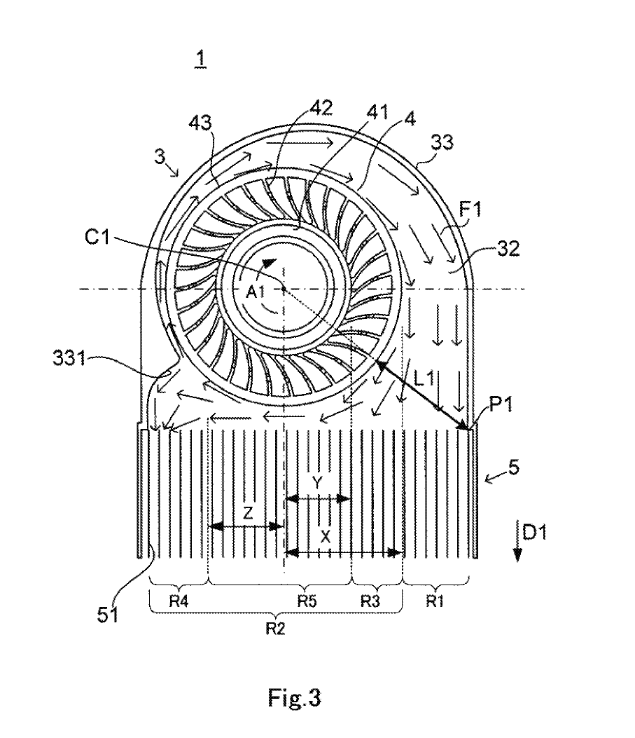

Referring to FIG. 3, the air blower 1 with the same configuration as the configuration in FIG. 2A will be described. On a straight line connecting the central axis C1 and a boundary position P1 upstream of the airflow F1 at which the inner surface of the side wall 33 and the inflow end of the exhaust unit 5 intersect, a line segment L1 connects the outer ends of the blades 42 of the impeller 4 and the boundary position P1. Part of the line segment L1 faces the first region R1 in the first direction D1.

In other words, on the straight line connecting the central axis C1 and the upstream boundary position P1 at which the inner surface of the side wall 33 and the inflow end of the exhaust unit 5 intersect, at least part of the line segment L1 extending from the outer ends of the blades 42 of the impeller 4 to the boundary position P1 faces the first region R1 in the first direction D1.

Thus, the small distance between the fins 51 in the first region R1 in which the flow of air is substantially parallel to the direction in which the fins 51 extend may allow the air volume to be adjusted, so that the air volume in the exhaust unit 5 may be made uniform in the direction in which the fins 51 are arrayed.

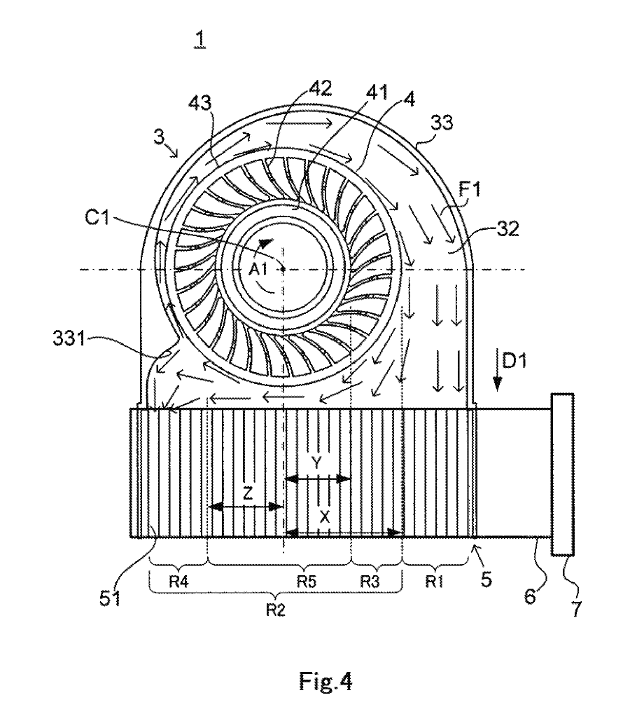

FIG. 4 is a plan view of the air blower 1 with a heat pipe viewed from above illustrating a configuration example thereof. In FIG. 4, the lower configuration of a heat pipe 6 is illustrated in transparent view for the sake of convenience.

The air blower 1 illustrated in FIG. 4 includes the heat pipe 6. The heat pipe 6 extends in the array direction of the fins 51 and is disposed in contact with the upper ends of the plurality of fins 51. The plurality of fins 51 are held by the heat pipe 6 and the lower plate 32 in the vertical direction. The exhaust unit 5 includes the fins 51, the heat pipe 6, and the lower plate 32. In this case, the fins 51 may be made of metal. The upper plate 31 (not illustrated in FIG. 4) extends to the boundary between the upper plate 31 and the heat pipe 6.

The heat pipe 6 is a component for transferring heat generated from a heat source component 7 to cool the heat source component 7. An example of the heat source component 7 is a central processing unit (CPU) 8. An example of the heat pipe 6 is a metal pipe containing a working fluid. The working fluid is evaporated by the heat generated from the heat source component 7. The evaporated working fluid moves in the heat pipe 6 toward the fins 51 and is cooled by the fins 51 into liquid. At this time, the heat is transferred to the fins 51. The liquefied working fluid is returned to the heat source component 7 due to capillarity, for example. The returned working fluid is evaporated again, and the operation is circulated.

The heat transferred from the heat pipe 6 to the fins 51 is further transferred to the air flowing in the gap between the fins 51. This allows efficiently cooling the heat source component 7. The configuration of the heat pipe 6 in FIG. 4 is given for mere illustrative purposes. For example, the heat pipe 6 may not be in contact with the upper ends of the fins 51 but may be in contact with the lower ends of the fins 51, or two heat pipes may be individually in contact with the upper ends and the lower ends of the fins 51. The heat pipe may be in contact with the fins 51 by passing through the fins 51 in the array direction of the fins 51. The heat pipe 6 may be in contact with the upper plate 31 or the lower plate 32. In this case, the upper plate 31 or the lower plate 32 may be made of a metal material having thermal conductivity.

In other words, the plurality of fins 51 are made of metal, and the air blower 1 includes the heat pipe 6 connected to the plurality of fins 51 along the array of the fins 51. This allows the heat of the heat pipe 6 to be transferred to the fins 51, thereby cooling the heat of the heat pipe 6 using the air flowing between the fins 51.

As illustrated in FIG. 4, the first region R1 is disposed at a portion of the heat pipe 6 adjacent to the heat source component 7. Thus, disposing the first region R1, in which air flows at a high speed, at a portion of the heat pipe 6 adjacent to the heat source component 7 allows efficient cooling.

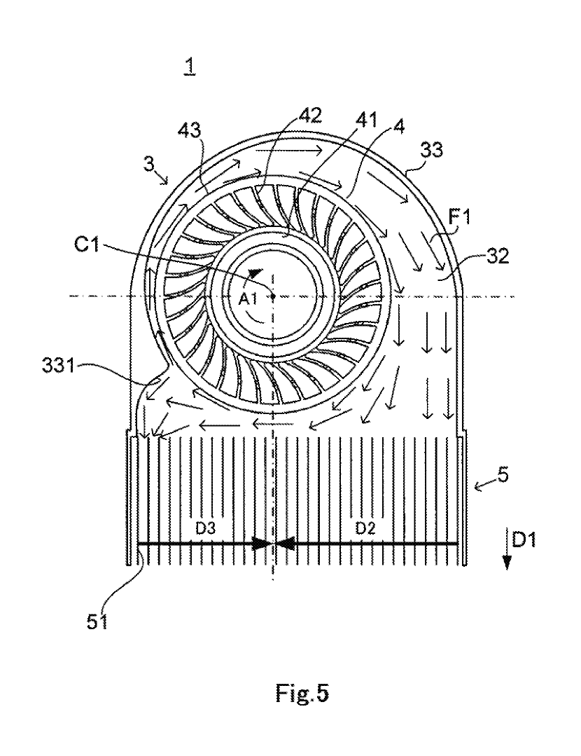

FIG. 5 is a diagram illustrating a modification of the configuration of the air blower 1 concerning the distance between the fins 51. In FIG. 5, the direction from the upstream end of the airflow F1 in the array of the fins 51 toward the line segment extending from the central axis C1 in the first direction D1 is represented as a direction D2, and the direction from the downstream end of the array of the fins 51 toward the line segment is represented as a direction D3.

In the air blower 1, the distance between the fins 51 gradually increases from the upstream end in the direction D2, and increases from the downstream end toward the direction D3. The air blower 1 illustrated in FIG. 5 satisfies the condition for the fin distances in the first predetermined distance X and the second predetermined distance Y described above.

In other words, the distance between the fins 51 gradually increases from both ends of the array of the fins 51 toward the line segment extending from the central axis C1 in the first direction D1. Thus, finely adjusting the distance between the fins 51 may make the volume of air uniform in the array direction of the fins 51 in the exhaust unit 5.

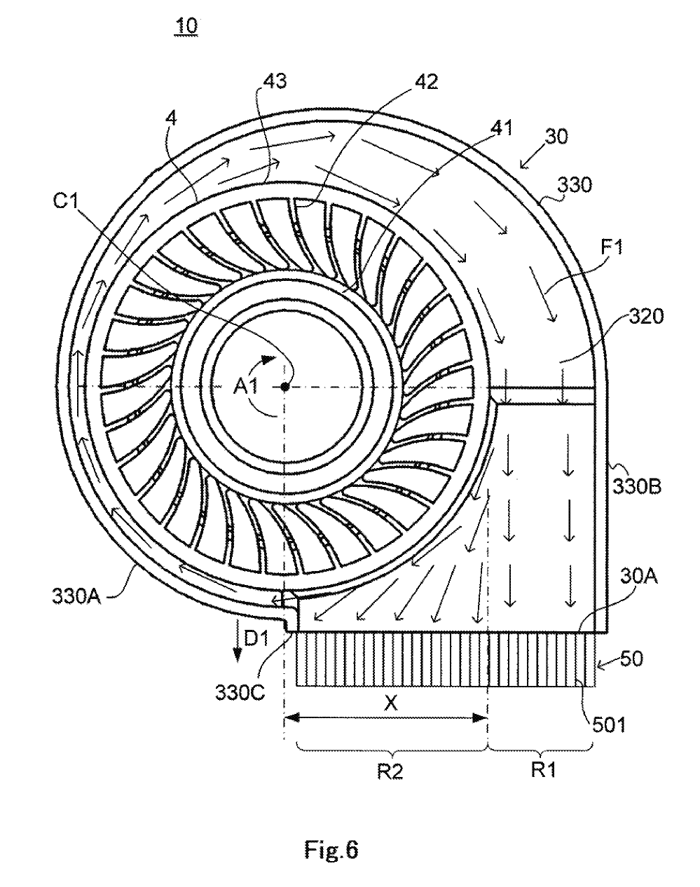

FIG. 6 is a plan view of an air blower 10 viewed from above illustrating an example in which the present disclosure is applied to a scroll air blower. In FIG. 6, the upper plate of a housing 30 is not illustrated.

The air blower 10 includes the housing 30, an impeller 4, and a motor unit (not illustrated). The impeller 4 and the motor unit are housed in the inner space of the housing 30. The impeller 4 is centered on the central axis C1 and has a configuration similar to the configuration of the embodiment described above. The motor unit is disposed inside the impeller 4 and rotates the impeller 4 about the central axis C1.

The housing 30 includes an upper plate (not illustrated), a lower plate 320, and a side wall 330. The lower plate 320 is positioned below the impeller 4 and the motor unit and extends in the radial direction. The motor unit is mounted to the lower plate 320. The side wall 330 extends upward from the peripheral edge of the lower plate 320.

The side wall 330 includes a curved surface 330A and flat surfaces 330B and 330C. The curved surface 330A is gradually separated from the central axis C in the rotational direction A1 of the impeller 4, as viewed from above. The flat surface 330B extends linearly from the downstream end of the curved surface 330A in the tangential direction in top view. The flat surface 330C extends radially outward from the upstream end of the curved surface 330A in top view. An air outlet 30A is formed between the downstream end of the flat surface 330B and the outer end of the flat surface 330C.

The upper plate (not illustrated) covers the upper opening of an accommodating space formed by the lower plate 320 and the side wall 330. The upper plate includes an air intake hole (an air intake portion) passing therethrough in the vertical direction. The air intake hole is positioned above the impeller 4. The air intake hole needs only be provided in at least one of the upper plate and the lower plate 320.

The air outlet 30A connects to an exhaust unit 50, which is a separate member from the housing 30. The exhaust unit 50 includes a plurality of fins 501. The exhaust unit 50 includes a lower cover and an upper cover that sandwich the fins 501 in the vertical direction. The upper cover is not illustrated in FIG. 6. The exhaust unit 50 is disposed in the first direction D1 with respect to the impeller 4.

When the impeller 4 is rotated in the rotational direction A1 by the motor unit, air is drawn into the housing 3 through the air intake hole and is blown radially outward between the blades 42 of the impeller 4. The blown-out air is regulated by the curved surface 330A and the flat surface 330B and is discharged through the air outlet 30A and gaps among the fins 501. FIG. 6 illustrates an airflow F1, which is the flow of air caused by the rotation of the impeller 4.

As illustrated in FIG. 6, it is assumed that the distance from the line segment extending from the central axis C1 in the first direction D1 to the array of the fins 501 upstream of the airflow F1 caused by the rotation of the impeller 4 is a first predetermined distance X. The plurality of fins 501 are located in a first region R1 located downstream from the first predetermined distance X and in a second region R2.

The distance between the fins 501 in the first region R1 is shorter than the distance between the fins 501 in the second region R2. In the second region R2, the direction of the airflow F1 is more inclined with respect to the extending direction of the fins 501 than in the first region R1. The large fin distance in the second region R2 may make the air easy to flow through the gap between the fins 501 to thereby increase the volume of air and the amount of exhaust air to be made uniform across the first region R1 and the second region R2.

In other words, the air blower 10, which is a scroll air blower, includes the impeller 4 centered on the central axis C1 extending in the vertical direction, the motor unit that rotates the impeller 4 about the central axis C1, and the housing 30 that houses the impeller 4. The housing 30 includes the lower plate 320, which covers the lower side of the impeller 4 and to which the motor unit is fixed, the side wall 330 covering a side of the impeller 4, and the upper plate covering the upper side of the impeller 4. At least one of the upper plate and the lower plate 320 includes an air intake portion. The exhaust unit 50 is disposed in the first direction D1, which is a radial component of the impeller 4. The exhaust unit 50 includes the plurality of fins 501. If the distance from the line segment extending from the central axis C1 in the first direction D1 to the array of the fins 501 upstream of the airflow F1 caused by the rotation of the impeller 4 is the first predetermined distance X, at least part of the plurality of fins 501 are disposed in the first region R1 located upstream from the first predetermined distance X and in the second region R2 located downstream from the first region R1. The distance between the plurality of fins 501 disposed in the first region R1 is shorter than the distance between the plurality of fins 501 disposed in the second region R2.

Thus, increasing the distance between the fins 501 in the second region R2 in which the airflow F1 is inclined with respect to the extending direction of the fins 501 may allow the air between the fins 501 to easily flow, thereby decreasing loss in air volume between the fins 501. This may increase the air flow rate of the air blower 10. This may also make the air volume in the exhaust unit 50 uniform in the direction in which the fins 501 are arrayed.

Although the plurality of fins according to the embodiments of the present disclosure have the same length in the first direction D1, this is given for mere illustrative purpose. The plurality of fins may be a combination of fins having different lengths. The axial length of the plurality of fins may also be a combination of different axial lengths on the air inflow side and the air discharge side.

While the example embodiments of the present disclosure have been described above, it is to be understood that various modifications of the example embodiments may be made without departing from the spirit and scope of the present disclosure. The present disclosure may be used in, for example, a centrifugal fan air blower.

What is claimed is:

1. An air blower comprising:
an impeller centered on a central axis extending in a vertical direction;
a motor to rotate the impeller about the central axis; and
a housing to house the impeller; wherein
the housing includes:
a lower plate covering a lower side of the impeller and fixed to the motor;
a side wall covering a side of the impeller; and
an upper plate covering an upper side of the impeller;
at least one of the upper plate and the lower plate includes an air intake portion;
an exhaust is disposed in a first direction that is a radial component of the impeller and includes a plurality of fins;
assuming that a distance from a line segment extending from the central axis in the first direction to an array of the fins upstream of an airflow caused by rotation of the impeller is a first predetermined distance, at least a portion of the plurality of fins are disposed in a first region located upstream from the first predetermined distance and in a second region located downstream from the first predetermined distance, and
a distance between the plurality of fins disposed in the first region is shorter than a distance between the plurality of fins disposed in the second region.

2. The air blower according to claim 1, wherein
assuming that a distance from the line segment extending from the central axis in the first direction to the array of the fins upstream of the airflow caused by the rotation of the impeller is a second predetermined distance, the second predetermined distance is shorter than the first predetermined distance;
the second region includes a third region upstream from the second predetermined distance and next to the first region; and
a distance between the plurality of fins disposed in the third region is longer than the distance between the plurality of fins disposed in the first region and shorter than a distance between the plurality of fins disposed in a remaining region of the second region other than the third region.

3. The air blower according to claim 2, wherein the second predetermined distance is from about 0.8 (Rin) to about 1.2 (Rin), where Rin is a distance from the central axis to radially inner ends of blades of the impeller.

4. The air blower according to claim 1, wherein
assuming that a distance from the line segment extending from the central axis in the first direction to an array of the fins downstream of the airflow caused by the rotation of the impeller is a third predetermined distance, the second region includes a fourth region downstream from the third predetermined distance; and
a distance between the plurality of fins disposed in the fourth region is shorter than a distance between the plurality of fins disposed in a remaining region of the second region other than the fourth region.

5. The air blower according to claim 4, wherein the side wall includes a tongued portion protruding toward the impeller, the tongued portion facing the fourth region in the first direction with a gap between the tongued portion and the fourth region.

6. The air blower according to claim 5, wherein the tongued portion includes a curved surface extending from a top facing the impeller toward the fourth region.

7. The air blower according to claim 1, wherein the second region is disposed at a position, on a line extending from the central axis toward the fin, where a distance between outer ends of blades of the impeller and inflow ends of the fins is shortest.

8. The air blower according to claim 1, wherein, on a straight line connecting the central axis and an upstream boundary position at which an inner surface of the side wall and an inflow end of the exhaust intersect, at least a portion of a line segment extending from outer ends of blades of the impeller to the upstream boundary position faces the first region in the first direction.

9. The air blower according to claim 1, wherein the plurality of fins are arrayed parallel or substantially parallel to the first direction.

10. The air blower according to claim 1, wherein the first predetermined distance is from about 0.8 (Rout) to about 1.2 (Rout), where Rout is a distance from the central axis to radially outer ends of blades of the impeller.

11. The air blower according to claim 1, wherein the distance between the fins increases from both ends of the array of the fins toward the line segment extending from the central axis in the first direction.

12. The air blower according to claim 1, further comprising:
a heat pipe connected to the plurality of fins along the array of the fins; wherein
the plurality of fins are made of metal.

13. The air blower according to claim 12, wherein the first region is disposed at a position of the heat pipe adjacent to a heat source component.
